(19) United States
(12) Patent Application Publication
(10) Pub. No.: US 2026/0282277 A1
(43) Pub. Date: Sep. 17, 2026

(54) ADAPTABLE LIQUID COOLANT FLOW LOOP FOR A SERVER

(71) Applicant: Lenovo Global Technology (United States) Inc., Morrisville, NC (US)

(72) Inventors: Benjamin Wakeford, Cary, NC (US); Keith Campbell, Cary, NC (US); Ayan Gulzar, Morrisville, NC (US); Elaine Dang, Durham, NC (US); Vinod Kamath, Raleigh, NC (US)

(21) Appl. No.: 19/079,672

(22) Filed: Mar. 14, 2025

(51) Int. Cl. H05K 7/20

(52) U.S. Cl. CPC H05K 7/20272; H05K 7/20254; H05K 7/20763

(57) ABSTRACT

A server includes heat-generating components and a flow loop providing a liquid coolant to cold plates in thermal communication with the heat-generating components. The flow loop includes, for each cold plate, one or more fluid flow segments for delivering the liquid coolant to and from the cold plate, wherein each fluid flow segment includes an electrically controllable upstream valve and an electrically controllable downstream valve. The apparatus further includes a plurality of liquid detection sensors, each sensor being co-located with a fluid flow segment. A controller included in the server is connected to each sensor and each valve. The controller executes program instructions to perform various operations, including receiving a positive liquid detection signal indicating liquid has contacted a specific sensor and sending a valve control signal to close the valves in the fluid flow segment that has a leak.

### BACKGROUND

The present disclosure relates to systems that use a liquid coolant to cool heat-generating components in a server.

### BACKGROUND OF THE RELATED ART

Computer servers generate significant heat due to the high processing power of their CPUs, GPUs, and other components, particularly in data centers or environments with dense hardware configurations. Liquid cooling with cold plates is often required to efficiently dissipate this heat and maintain optimal performance. Cold plates, which are flat metal plates with embedded liquid channels, are placed directly against heat-generating components. The liquid flowing through these channels absorbs the heat and carries it away to an external radiator or cooling unit, where it is released. This method provides superior thermal management compared to air cooling, as liquid has a higher heat capacity and thermal conductivity than air. Liquid cooling with cold plates also enables quieter operation, as it reduces the need for high-speed fans, and supports the growing demand for compact, high-performance servers in energy-efficient and space-constrained environments.

If a liquid cooling tube in a computer server develops a leak, it can cause severe damage to the server and its components. The leaked liquid, often a conductive coolant, can come into contact with sensitive hardware such as the motherboard, CPU, GPUs, and memory modules, leading to short circuits. This can result in immediate system failures, data loss, or permanent damage to critical components. Even non-conductive coolants can cause corrosion or residue buildup over time, impairing functionality. A leak can also disrupt the cooling system's effectiveness, causing overheating and potentially triggering thermal shutdowns or component degradation. Additionally, repairing such damage often involves extensive downtime, increased maintenance costs, and, in extreme cases, the replacement of entire servers. To minimize these risks, liquid sensors may be used to detect a leak in the cooling system and trigger a shutdown of the server until service can be performed.

### BRIEF SUMMARY

Some embodiments provide an apparatus comprising a server including a plurality of heat generating components and a flow loop for providing a liquid coolant to a plurality of cold plates, wherein each cold plate is positioned in thermal communication with one of the heat generating components. The flow loop includes, for each cold plate, one or more fluid flow segments for delivering the liquid coolant to and from the cold plate, wherein each of the one or more fluid flow segments includes an electrically controllable upstream valve at an upstream end of the fluid flow segment and an electrically controllable downstream valve at a downstream end of the fluid flow segment. The apparatus further comprises a plurality of liquid detection sensors, wherein each liquid detection sensor is co-located with a respective one of the fluid flow segments. Still further, the apparatus comprises a controller included in the server and connected to each of the liquid detection sensors, each of the electrically controllable upstream valves and each of the electrically controllable downstream valves. The controller includes a processor configured to process program instructions, wherein the program instructions are configured to, when processed by the processor, cause the processor to perform operations comprising: receiving, from one or more of the liquid detection sensors, a positive liquid detection signal indicating that the liquid coolant has contacted the liquid detection sensor; and sending, for each positive liquid detection signal received, a valve control signal to close the electrically controllable upstream valve and the electrically controllable downstream valve of the fluid flow segment that includes the liquid detection sensor that generated the positive liquid detection signal.

### BRIEF DESCRIPTION OF THE SEVERAL VIEWS OF THE DRAWINGS

FIG. 1 is a diagram of the layout of two liquid-cooling flow loops that support the flow of a liquid to cold plates that are in thermal communication with components in a server according to some embodiments.

FIG. 2 is a diagram of a baseboard management controller according to some embodiments.

FIG. 3 is a schematic diagram of a server in which the liquid-cooled components may operate according to some embodiments.

FIG. 4A is a diagram of one of the liquid-cooling flow loops of FIG. 1 identifying the locations of liquid sensor strings or ropes and electronically controlled valves according to some embodiments.

FIG. 4B is a diagram of the liquid-cooling flow loop of FIG. 4A in which the liquid sensor strings or ropes are replaced with discrete liquid sensor elements according to some embodiments.

FIG. 5A is a diagram of the liquid-cooling flow loop of FIG. 4A identifying a manner in which the electronically controlled valves may be operated to maintain the flow of a liquid to the cold plates in thermal communication with heat generating components when the liquid sensor elements are not detecting any leaks according to some embodiments.

FIG. 5B is a diagram of the liquid-cooling flow loop of FIG. 4A identifying a manner in which the electronically controlled valves may be operated to maintain the flow of the liquid to the cold plates while shutting off the flow of liquid to leaking segments of the flow loop when the liquid sensor elements have detected liquid (leaks) in four specific segments of the flow loop according to some embodiments.

FIG. 6 is a side view of a segment of a liquid-cooling flow loop including a cold plate and upstream and downstream flow control valves.

### DETAILED DESCRIPTION

Some embodiments provide an apparatus comprising a server including a plurality of heat generating components and a flow loop for providing a liquid coolant to a plurality of cold plates, wherein each cold plate is positioned in thermal communication with one of the heat generating components. The flow loop includes, for each cold plate, one or more fluid flow segments for delivering the liquid coolant to and from the cold plate, wherein each of the one or more fluid flow segments includes an electrically controllable upstream valve at an upstream end of the fluid flow segment and an electrically controllable downstream valve at a downstream end of the fluid flow segment. The apparatus further comprises a plurality of liquid detection sensors, wherein each liquid detection sensor is co-located with a respective one of the fluid flow segments. Still further, the apparatus comprises a controller included in the server and connected to each of the liquid detection sensors, each of the electrically controllable upstream valves and each of the electrically controllable downstream valves. The controller includes a processor configured to process program instructions, wherein the program instructions are configured to, when processed by the processor, cause the processor to perform operations comprising: receiving, from one or more of the liquid detection sensors, a positive liquid detection signal indicating that the liquid coolant has contacted the liquid detection sensor; and sending, for each positive liquid detection signal received, a valve control signal to close the electrically controllable upstream valve and the electrically controllable downstream valve of the fluid flow segment that includes the liquid detection sensor that generated the positive liquid detection signal.

The flow loop has a first upstream end that connects with a liquid coolant source and a second downstream end that connects with a liquid coolant return or drain. A coolant distribution unit (CDU), also referred to as a cooling distribution unit, may include or be connected to both the liquid coolant source and the liquid coolant return. Accordingly, the coolant distribution unit may receive the liquid coolant at the liquid coolant return, remove heat from the received liquid coolant, and then supply the liquid coolant to the liquid coolant source. The flow loop(s) in the server(s) receive the cooled liquid coolant from the liquid coolant source and deliver the cooled liquid coolant to the cold plates in the flow loop. Since each cold plate is positioned in thermal communication with one of the heat generating components, the heat is transferred from the heat generating component into the cold plate and carried away in the flowing liquid coolant. As the liquid coolant takes on heat from one or more cold plates, the temperature of the liquid coolant rises, and the warmed liquid coolant is then delivered to the liquid coolant return. Accordingly, the liquid coolant may be circulated through a closed loop system in which the liquid coolant takes on the heat of the heat generating components as it flows through the flow loop(s) of the server(s) and then give up that heat as it flows through a heat exchange or radiator portion of the coolant distribution unit.

Each fluid flow segment forms a portion or segment of the flow loop. Each fluid flow segment includes an electrically controllable upstream valve at an upstream end of the fluid flow segment and an electrically controllable downstream valve at a downstream end of the fluid flow segment, with one or more cold plate positioned within the fluid flow segment. Accordingly, each fluid flow segment delivers the liquid coolant to and from the one or more cold plate within the fluid flow segment. It should be understood that each fluid flow segment may include more than one piece of tubing. For example, a fluid flow segment that delivers liquid coolant to a single cold plate will include a first piece of tubing may form a connection between the electrically controllable upstream valve and an inlet to the cold plate, and a second piece of tubing may form a connection between an outlet from the cold plate to the electrically controllable downstream valve.

The liquid coolant used in the cooling of the server may be water or a water-based solution. These liquid coolants may include deionized water alone or mixed with additives like ethylene glycol or propylene glycol to prevent freezing and corrosion. Tubing material that is compatible with water or the water-based solutions may, without limitation, include polyvinyl chloride (PVC), acrylic, ethylene-propylene-diene monomer (EPDM), polyethylene terephthalate glycol (PETG), copper, and stainless steel.

The apparatus further comprises a plurality of liquid detection sensors, wherein each liquid detection sensor is co-located with a respective one of the fluid flow segments. With a specific liquid detection sensor being positioned in the same location as a specific fluid flow segment, any liquid detected by that sensor is associated with a leak being present in the associated or co-located fluid flow segment. Each leak detection device is connected to a controller to provide an output signal informing the controller when liquid has been detected. Accordingly, the controller will identify a fluid flow segment where a leak is occurring based on which liquid sensor is sending a positive leak (liquid detection) signal. The controller may then close the valves on either end of the identified fluid flow segment so that the leak is stopped (i.e., no more liquid is supplied to the fluid flow segment experiencing the leak). In one option, the controller is a baseboard management controller (BMC).

A liquid detection sensor or leak detection sensor may detect contact with the liquid coolant, such as water, using conductive sensing technology. The sensor may have exposed electrodes or conductive materials that complete an electrical circuit when water comes into contact with them. Since water is a conductor, the presence of even a small amount of water bridges the gap between these electrodes, allowing an electric current to flow. This change in conductivity may be interpreted as the presence of a leak. The liquid detection sensors may include sensitive electronics to detect even minute amounts of water and produce a liquid detection signal that is output to the controller. Furthermore, the liquid detection sensor may be a discrete sensor element or a liquid detection string or rope that is designed to detect liquid coolant along its entire length using a network of conductive and non-conductive materials. The rope is typically composed of braided or woven fibers with embedded conductive elements that are separated by small gaps or insulating materials. When water or other conductive liquid contacts any part of the rope, it bridges the gap between the conductive elements, completing an electrical circuit and triggering a signal. This design allows the rope to monitor for contact with liquid coolant along its entire length, making the leak detection rope ideal for detecting leaks that occur in a fluid flow segment even in hard-to-reach or extended spaces, such as an area under the fluid flow segment, around the cold plate, or along the edges of a processor socket supporting the heat generating component.

In some embodiments, the plurality of heat-generating components may include one or more central processing units, one or more graphics processing units, one or more memory modules, one or more hard drives and/or one or more expansion cards. High performance central processing units (CPUs) and graphics processing units (GPUs) are the most likely components to require liquid cooling. However, the architecture of a server may vary and the number and type of heat-generating components that require liquid cooling may also vary. Accordingly, the configuration and content of the flow loop may vary from one server to another according to the cooling requirements of the server. For example, the number of cold plates may vary as a function of the number of heat-generating components that require liquid cooling, and the configuration of the fluid flow segments may vary as a function of the layout of the heat-generating components on the system board.

In some embodiments, the flow loop may include, for each cold plate, first and second fluid flow segments that each deliver liquid to and from the cold plate, wherein the first fluid flow segment has a flow path that is independent from the flow path of the second fluid flow segment. Under normal conditions with no leaks, the dual, parallel flow paths through the cold plate formed by the first and second fluid flow segments can be used at the same time for optimal flow, or one flow path at a time. If a leak has been detected in one of the two fluid flow segments, then the fluid flow segment with the leak can be shut off or isolated by closing the upstream and downstream valves in the leaking fluid flow segment. However, liquid coolant can continue to be supplied to the cold plate by the non-leaking fluid flow segment such that the heat-generating component in thermal communication with the cold plate may still be cooled. If the non-leaking fluid flow segment does not provide a sufficient flow rate of liquid coolant to the cold plate to support full operation of the heat-generating component, then the heat-generating component may be throttled to maintain a desired operating temperature.

In some embodiments, the flow loop further includes, for a first cold plate of the plurality of cold plates, a liquid bypass fluid flow segment that directs at least some of the liquid coolant to a path isolated from the first cold plate, wherein the liquid bypass fluid flow segment includes one or more electrically controllable valves. Accordingly, the one or more electrically controllable valves may be used to control the flow of liquid coolant through the liquid bypass tubing. In one option, the one or more electrically controllable valves in the liquid bypass fluid flow segment are normally closed to direct liquid coolant through the fluid flow segments that deliver liquid coolant to and from the particular cold plate. However, if one or both of the fluid flow segments that deliver liquid coolant to and from the first cold plate (i.e., the principal fluid flow segments) are closed off as a result of a leak in one or both of those fluid flow segments, then the valve(s) in the liquid bypass fluid flow segment may be opened to enable liquid coolant to continue flowing through the flow loop. Where fluid flow segments deliver liquid coolant to multiple cold plates, then the liquid bypass fluid flow segment may pass around all of the multiple cold plates.

In some embodiments, the liquid bypass fluid flow segment may include first and second electrically controllable valves and a liquid detection sensor co-located with the liquid bypass fluid flow segment, wherein the controller is connected to the liquid detection sensor that is co-located with the liquid bypass fluid flow segment, the first electrically controllable valve and the second electrically controllable downstream valve. Accordingly, the controller may close the valves on the ends of the liquid bypass fluid flow segment in response to receiving a positive liquid detection signal from the co-located liquid detection sensor. If the valves in the fluid flow segments that deliver liquid coolant to one of the cold plates are already closed, then closing the valve(s) in the bypass fluid flow segment may disrupt flow to the rest of the flow loop such that the entire server should be shut down.

In some embodiments where the flow loop includes, for each cold plate, first and second principal fluid flow segments providing independent flow paths for delivering liquid to and from the cold plate, the operations of the controller may further comprise monitoring, for each fluid flow segment that delivers the liquid coolant to and from one of the cold plates, output from the liquid detection sensor that is co-located with the fluid flow segment. Still further, the operations of the controller may comprise causing, for each fluid flow segment that delivers the liquid coolant to and from one of the cold plates, the electrically controllable upstream valve and the electrically controllable downstream valve at the ends of the fluid flow segment to be open so that liquid coolant flows to and from the cold plate through the fluid flow segment in response to the output from the liquid detection sensor that is co-located with the fluid flow segment indicating that the liquid detection sensor is not in contact with the liquid. In one option, the operations may further comprise causing, in response to receiving a positive liquid detection signal from the liquid detection sensor in one of the first and second fluid flow segments that deliver the liquid coolant to and from one of the cold plates (i.e., one of the principal fluid flow segment), the one or more flow control valves in the liquid bypass fluid flow segment to open. In a further option, the operations may further comprise causing, in response to receiving a positive liquid detection signal from the liquid detection sensor in both of the first and second fluid flow segments that deliver the liquid coolant to and from one of the cold plates (i.e., both of the principal fluid flow segments), the one or more flow control valves in the liquid bypass fluid flow segment to open and the heat generating component that is in thermal communication with the cold plate to be taken offline.

In some embodiments, the operations may further comprise causing, in response to receiving a positive liquid detection signal from the liquid detection sensor in each of the one or more principal fluid flow segments that deliver the liquid coolant to and from one of the cold plates, the heat generating component that is in thermal communication with the cold plate to be taken offline and the one or more flow control valves in the liquid bypass fluid flow segment to open. Still further, the operations may comprise allowing the server to continue in operation after the heat generating component has been taken offline. For example, a graphics processing unit (GPU)/Open Compute Project (OCP) Accelerator Module (OAM), or any other component in the server or computer system such as a memory, hard drive or PCIe card, in the area may be taken offline (hotplug) using downstream port containment and the power to that area/GPU/OAM can be controlled to prevent damage due to the leak in that area, while the rest of the system continues to operate.

In some embodiments, each of the electrically controllable upstream valves and each of the electrically controllable downstream valves may include a closure element that is coupled to an electronic actuator, wherein the electronic actuator is adapted to move the closure element to open or close an opening through a body of the valve responsive to the valve control signal received by the valve. For example, the electrically controllable upstream and downstream valves may be electric solenoid valves. Non-limiting examples of the closure element (obstructor) include a wedge, plug, ball, gate, plunger, shuttle, spool or diaphragm. In some embodiments, the valves may be referred to as stop valves, block valves, on-off valves or 2-position valves. Variable flow control valves could also be used.

In some embodiments, the flow loop may include at least one fluid flow segment that delivers the liquid coolant to and from two or more cold plates in series. For example, the fluid flow segment may include a first tubing piece that connects the upstream valve to an inlet to the a first cold plate, a second tubing piece that connects an outlet form the first cold plate to an inlet of a second cold plate, and a third tubing piece that connects an outlet from the second cold plate to the downstream valve. Optionally, multiple parallel fluid flow segments may deliver the liquid coolant to the two or more cold plates in the same manner.

In some embodiments, the flow loop may include a plurality of manifolds, wherein each manifold is connected to a plurality of electrically controllable downstream valves at the downstream end of the fluid flow segments delivering the liquid coolant to a first one of the cold plates and/or a plurality of electrically controllable upstream valves at the upstream end of the fluid flow segments delivering the liquid coolant to a second one of the cold plates. The manifold may be formed by tubing that has multiple inputs for connecting to the downstream fluid flow segments, such as the downstream valves of a first plurality of fluid flow segments, and multiple outputs for connecting to the upstream fluid flow segments, such as the upstream valves of a second plurality of fluid flow segments. Accordingly, the manifold enables the flow of the liquid coolant from any one or more of the principal fluid flow segments and/or bypass fluid flow segments associated with a first cold plate to any one or more of the principal and/or bypass fluid flow segments associated with a second cold plate.

In some embodiments, the apparatus may further comprise a coolant distribution unit in fluid communication with the flow loop, wherein the coolant distribution unit supplies the liquid coolant to an upstream end of the flow loop and receives the liquid coolant from a downstream end of the flow loop. The coolant distribution unit may be connected to the flow loops of a plurality of servers, such as each of the servers in one or more racks of servers.

In some embodiments, the apparatus may further comprise a thin film heater positioned within the server and under the fluid flow segment. The operations of the controller may further comprise controlling the thin film heater to increase evaporation of liquid present under the fluid flow segment in response to receiving the positive liquid detection signal from one or more of the liquid detection sensors co-located with that particular fluid flow segment. A thin film heater is a flexible, low-profile heating element made from a very thin layer of conductive material, typically deposited on a substrate like polyimide or the system board. The thin film heater may provide heat in tight spaces with minimal thickness and precise control over the heat output. For example, a thin film heater may be positioned or formed under connections or fittings that are most likely to leak and may be arranged in cooperation with a fluid containment tray or reservoir. Although the apparatus may not quantify the amount of liquid present, the thin film heater may be used to accelerate evaporation of any liquid that is present. Optionally, the thin film heater may be activated until the liquid detection sensor, such as a liquid detection sensor rope, no longer outputs a positive liquid detection signal.

In some embodiments, the apparatus may further comprise one or more fans directed to cause air flow across the fluid flow segment co-located with a liquid detection sensor that has detected a leak. The operations of the controller may further comprise increasing the speed of the one or more fans to increase evaporation of liquid present under or around the fluid flow segment in response to receiving the positive liquid detection signal from one or more of the liquid detection sensors within that particular fluid flow segment.

In some embodiments, the operations of the controller may further comprise notifying one or more users that a positive liquid detection signal has been received. A notification may optionally further include information identifying the location of the leak, such as a server identifier or location and/or a component or fluid flow segment identifier or location. Still further, the notification may optionally include some indication of the fluid flow segments that are currently closed and whether any of the heat-generating components have been shut down.

In some embodiments of the apparatus, the server may include a first plurality of heat generating components and a second plurality of heat generating components. The apparatus may further include a first flow loop for providing a liquid coolant to a first plurality of cold plates that are each positioned in thermal communication with one of the heat generating components in the first plurality of heat generating components and a second flow loop for providing the liquid coolant to a second plurality of cold plates that are each positioned in thermal communication with one of the heat generating components in the second plurality of heat generating components. Each of the first and second flow loops may be configured and/or operated in accordance with any of the embodiments of a flow loop described herein. For example, both of the first and second flow loops may be coupled to the same liquid coolant source and the same liquid coolant return. Furthermore, the electrically controllable upstream and downstream valves in each fluid flow segment of each flow loop may be controlled by the same controller.

It is a technical benefit of some embodiments that a server having a liquid coolant leak may continue to operate in a reduced state, maximizing server uptime while preventing damage to the system board of the server due to the leak. High performance servers and server racks are expensive and embodiments that enable the server to continue operation even with reduced capacity are highly valuable to the server end user. It is also a technical benefit of some embodiments that a liquid leak in a server does not have to be treated as an emergency. Rather, the repair of a liquid coolant leak in a section of the coolant flow loop in a server may be delayed until a planned maintenance window. It is a further technical benefit of some embodiments that the coolant flow rate and/or pressure to the server and/or the entire rack of servers (or multiple racks) may be maintained even when a leak occurs. Accordingly, there may be no significant impact on the operation of the coolant distribution unit (CDU) that supplies the coolant to the server or rack and removes heat from the coolant.

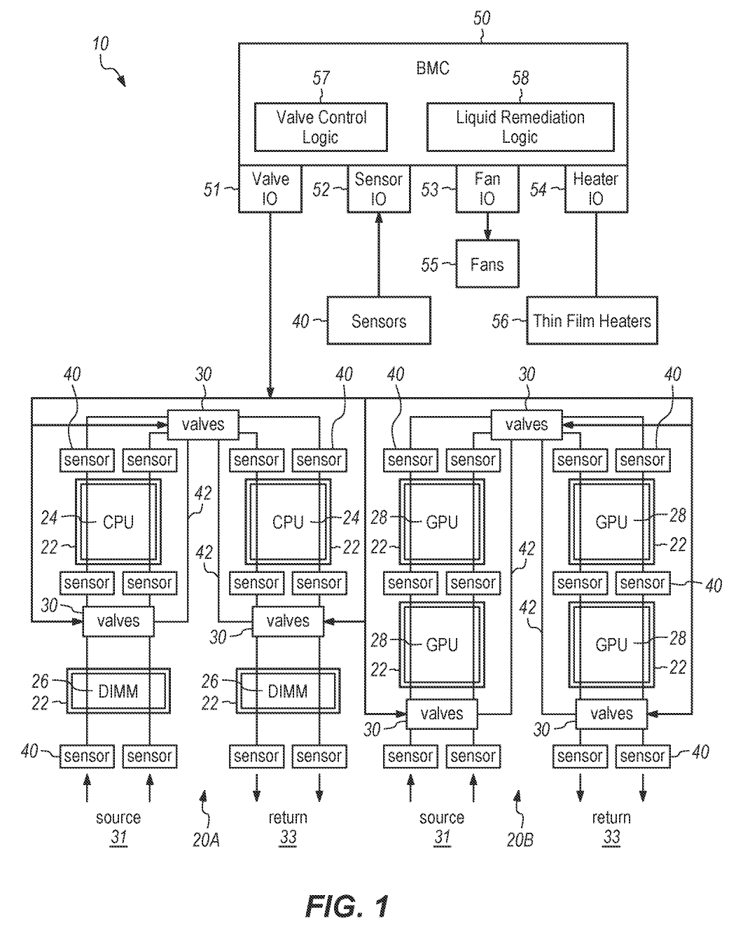

FIG. 1 is a schematic diagram of a server 10 showing a general layout of two liquid-cooling flow loops 20A, 20B that support the flow of a liquid coolant to cold plates 22 that are in thermal communication with components (CPUs 24, DIMMs 26, GPUs 28) in the server 10 according to some embodiments. The flow loops 20A, 20B also include electrically controllable valves 30 and liquid detection sensors 40.

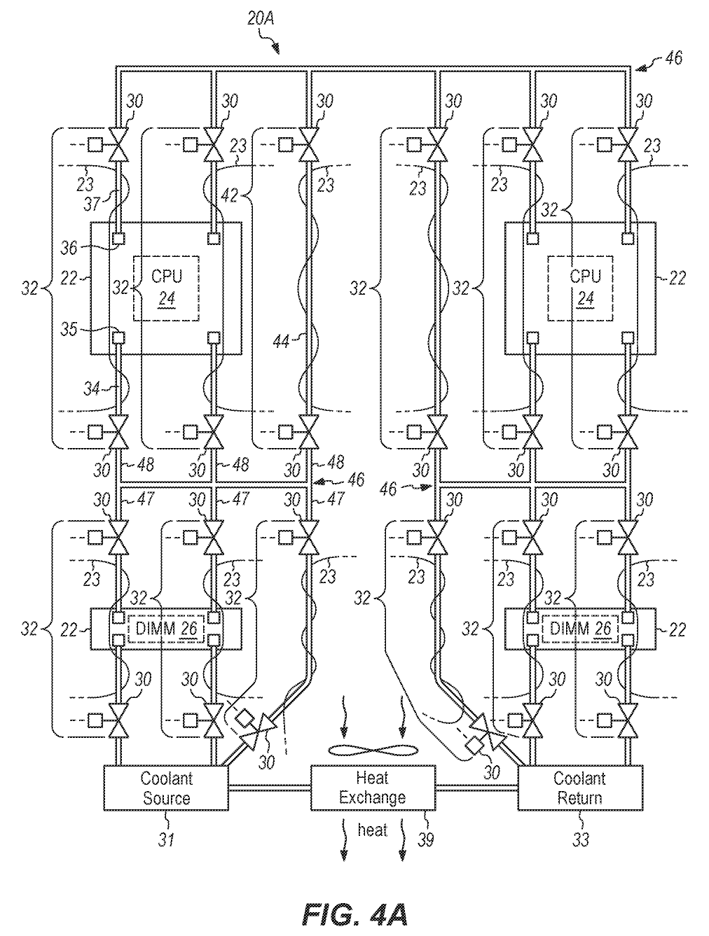

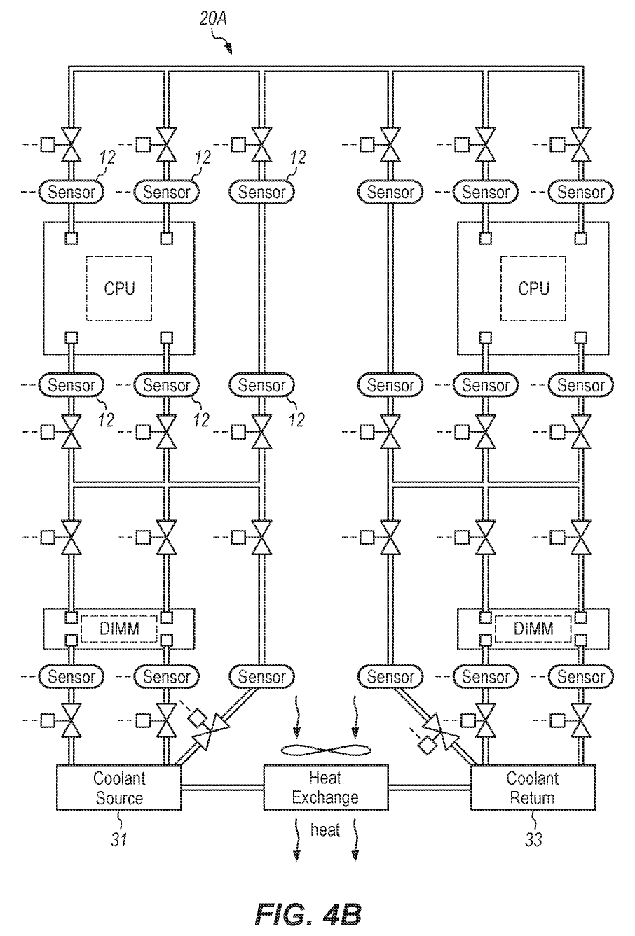

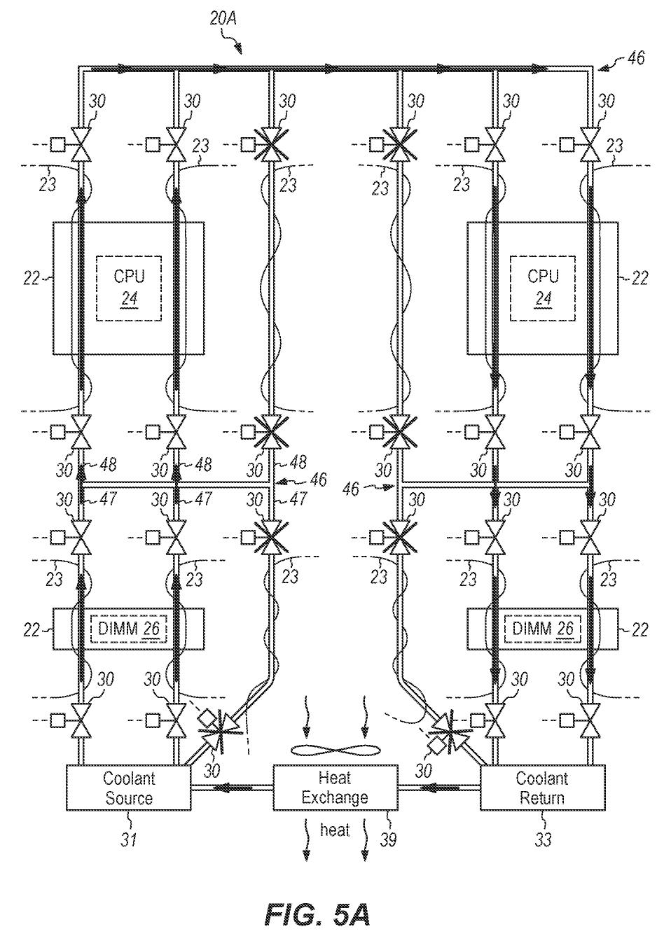

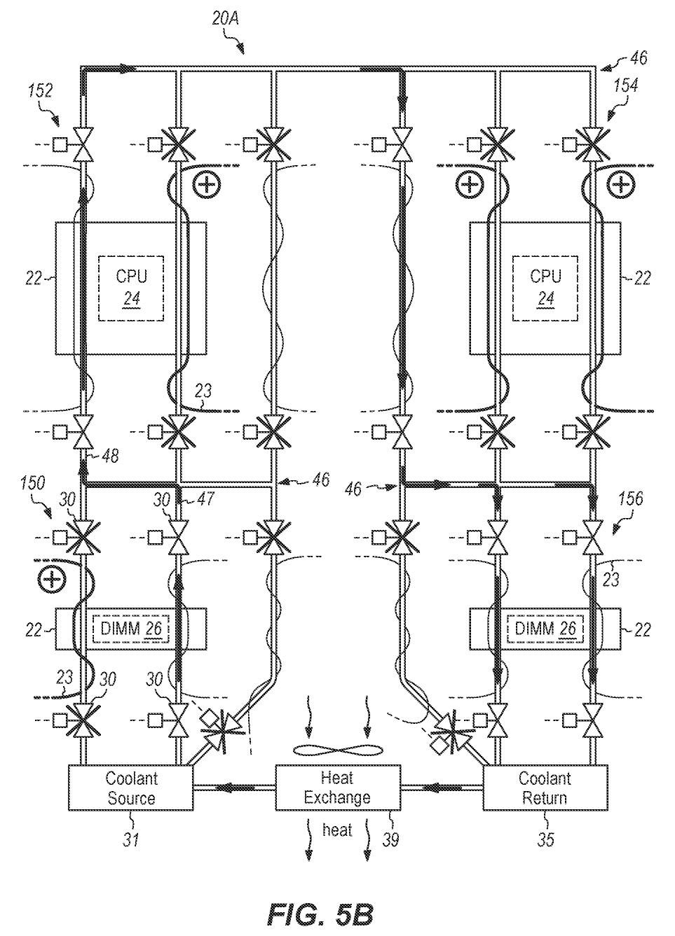

Each of the flow loops 20, 50 has a first end coupled to a liquid coolant source 31 and a second end coupled to a liquid coolant return 33. Each of the flow loops 20A, 20B has two principal fluid flow segments establishing parallel flow paths for delivering liquid coolant to each of the cold plates 22. Four bypass fluid flow segments 42 are also shown for directing liquid coolant around cold plates. More detailed diagrams of the flow loop 20 are provided in FIGS. 4A-5B.

The server 10 also includes a controller in the form of a baseboard management controller 50. The baseboard management controller 50 has valve I/O ports 51 connected to the valves 30, sensor I/O ports 52 connected to the sensors 40, fan I/O ports 53 connected to a plurality of fans 55, and heater I/O ports 54 connected to a plurality thin film heaters 56. The locations of the valves 30, sensors 40, fans 55 and thin film heaters 56 will be discussed in more detail below.

The baseboard management controller 50 may execute valve control logic 57 which controls the valves 30 in response to input from the sensors 40. The baseboard management controller 50 may also execute liquid remediation logic 58 which controls the fans 55 and/or thin film heaters 56 in response to input from the sensors 40.

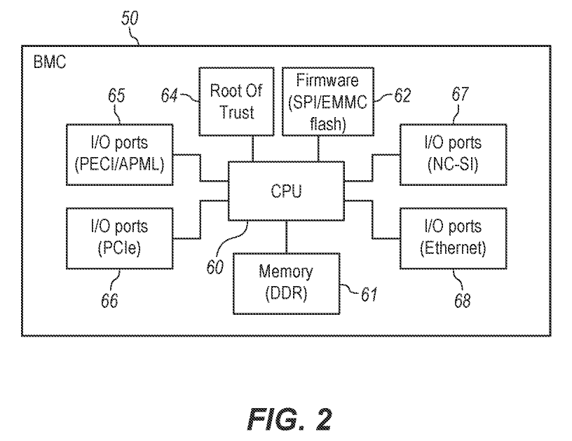

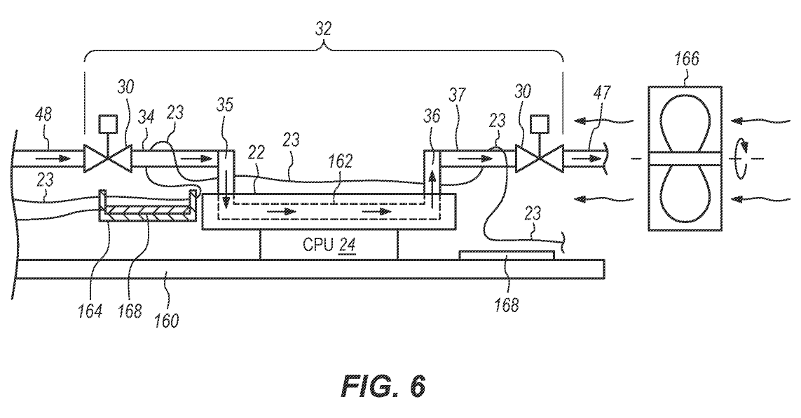

FIG. 2 is a diagram of a baseboard management controller (BMC) 50 according to some embodiments. The BMC 50 is similar to a small computer or system on a chip (SoC), including a central processing unit (CPU) 60 (which is a separate entity from the central processing units 16, 17 in FIG. 1 and processor 104 of FIG. 6), memory 61 (such as random-access memory (RAM) on a double data rate (DDR) bus), firmware 62 on a flash memory (such as an embedded multi-media card (eMMC) flash memory or a serial peripheral interface (SPI) flash memory), and a root of trust (RoT) chip 64. The BMC 50 further includes a wide variety of input/output ports. For example, the input/output (I/O) ports may include I/O ports 65 to the hardware components of the server, such as a Platform Environment Control Interface (PECI) port and/or an Advanced Platform Management Link (APML) port; I/O ports 66 to the hardware components of the servers and/or a network interface controller (NIC), such as a Peripheral Component Interconnect Express (PCIe) port; I/O ports 67 to the NIC, such as a network controller sideband interface (NC-SI) port; and I/O ports 68 to a network that is accessible to an external user, such as an Ethernet port. The BMC 50 may use any one or more of these I/O ports to interact with hardware devices installed on the server 10 for purposes of monitoring and control.

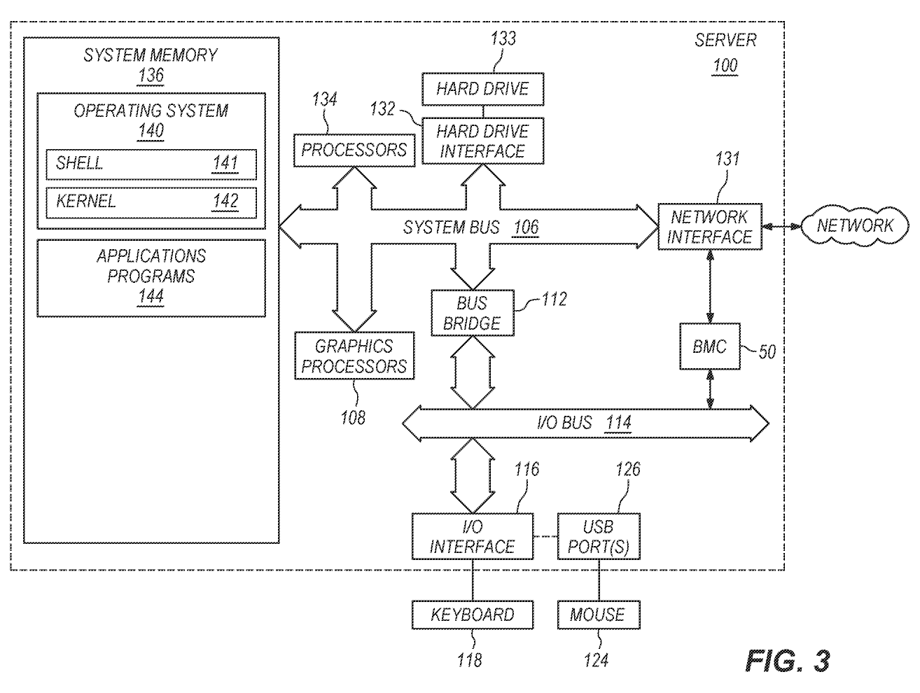

FIG. 3 is a schematic diagram of a server 100 in which the liquid-cooled components may operate according to some embodiments. The server 100 may be representative of the server 10 in FIG. 1. For example, the server 100 includes processors 134 that may represent the CPUs 24 in FIG. 1, system memory 136 that may represent the DIMMs 22 in FIG. 1, and the graphics processors 108 that may represent the GPUs 28 in FIG. 1.

The server 100 includes a processor unit 134 that is coupled to a system bus 106. The processor unit 104 may utilize one or more processors, each of which has one or more processor cores. A graphics processor 108 is also coupled to system bus 106. The system bus 106 may be coupled via a bus bridge 112 to an input/output (I/O) bus 114. An I/O interface 116 is coupled to the I/O bus 114, where the I/O interface 116 affords a connection with various optional I/O devices, such as a keyboard 118 (such as a touch screen virtual keyboard), and a USB mouse 124 via USB port(s) 126 (or other type of pointing device, such as a trackpad). As depicted, the computer 100 is able to communicate with other network devices over a network using a network adapter or network interface controller 131.

A hard drive interface 132 is also coupled to the system bus 106. The hard drive interface 132 interfaces with a hard drive 133. In a preferred embodiment, the hard drive 133 may communicate with system memory 136, which is also coupled to the system bus 106. The system memory may be volatile or non-volatile and may include additional higher levels of volatile memory (not shown), including, but not limited to, cache memory, registers and buffers. Data that populates the system memory 136 may include the operating system (OS) 140 and application programs 144. The hardware elements depicted in the server 100 are not intended to be exhaustive but rather are representative.

The operating system 114 includes a shell 141 for providing transparent user access to resources such as application programs 144. Generally, the shell 141 is a program that provides an interpreter and an interface between the user and the operating system. More specifically, the shell 141 may execute commands that are entered into a command line user interface or from a file. Thus, the shell 141, also called a command processor, is generally the highest level of the operating system software hierarchy and serves as a command interpreter. The shell may provide a system prompt, interpret commands entered by keyboard, mouse, or other user input media, and send the interpreted command(s) to the appropriate lower levels of the operating system (e.g., a kernel 142) for processing. Note that while the shell 141 may be a text-based, line-oriented user interface, the present invention may support other user interface modes, such as graphical, voice, gestural, etc.

As depicted, the operating system 140 also includes the kernel 142, which includes lower levels of functionality for the operating system 140, including providing essential services required by other parts of the operating system 140 and application programs 144. Such essential services may include memory management, process and task management, disk management, and mouse and keyboard management. In addition, the computer server 100 may include application programs 144 stored in the system memory 136.

The server 100 may further include a baseboard management controller (BMC) 50. The BMC is considered to be an out-of-band controller and may monitor and control various components of the server 100. However, the BMC may also communicate with various devices via the network interface 131 and one or more network(s).

FIG. 4A is a diagram of the liquid-cooling flow loop 20A of FIG. 1 identifying the locations of cold plates 22 (four shown) that are in thermal communication with the CPUs 24 and DIMMs 26, the locations of the liquid detection sensor strings or ropes 23 (twelve shown), and the locations of the electronically controlled valves 30 (twenty-four shown) according to some embodiments. For each of the cold plates 22, there are two principal fluid flow segments 32 that deliver liquid coolant to and from the cold plate 22. Specifically, each principal fluid flow segment 32 includes an electrically controllable upstream valve 30, a first piece of tubing 34 that forms a connection between the electrically controllable upstream valve 30 and an inlet 35 to the cold plate 22, a second piece of tubing 37 that forms a connection between an outlet 36 from the cold plate 22 to the electrically controllable downstream valve 30, as well as the electrically controllable downstream valve 30 itself.

For each of the cold plates 22, there is one bypass fluid flow segment 42 that directs liquid coolant to a path isolated from the cold plate 22 (i.e., the flow path does not go through the cold plate). Specifically, each bypass fluid flow segment 32 includes an electrically controllable upstream valve 30, a piece of tubing 44 that forms a connection between the electrically controllable upstream valve 30 and an electrically controllable downstream valve 30, as well as the electrically controllable downstream valve 30 itself.

The portion of the flow loop 20A from the coolant source 31 through the cold plates 22 to the coolant return 33 includes the fluid flow segments 32, 42 as a plurality of coolant manifolds 46 (three shown). Each manifold is connected to a plurality of electrically controllable downstream valves 30 at the downstream end of some fluid flow segments delivering the liquid coolant to a first one of the cold plates 22 and/or a plurality of electrically controllable upstream valves 30 at the upstream end of other fluid flow segments delivering the liquid coolant to a second one of the cold plates 22. A manifold 46 may be formed by tubing that has multiple inputs 47 for connecting to the upstream fluid flow segments, such as the downstream valves of a first plurality of fluid flow segments, and multiple outputs 48 for connecting to the downstream fluid flow segments, such as the upstream valves of a second plurality of fluid flow segments. Accordingly, each manifold 46 enables the flow of the liquid coolant from any one or more of the principal fluid flow segments 32 and/or bypass fluid flow segments 42 associated with a first cold plate to any one or more of the principal fluid flow segments 32 and/or bypass fluid flow segments 42 associated with a second cold plate 22 that is downstream of the first cold plate 22. In FIG. 4A, each of the three manifolds 46 has three inputs and three outputs.

Liquid coolant that has passed through the flow loop 20A is provided to the coolant return 33. While the coolant return 33 could be a drain, it is more desirable to recycle the liquid coolant. Accordingly, the coolant return 33 may direct the liquid coolant to a heat exchanger 39 (also referred to as a “radiator”) where heat is removed from the (warmed) liquid coolant before directing the (cooled) liquid coolant to the coolant source 31 for further cooling of the components 24, 26 in the server.

One of the liquid detection sensor strings or ropes 23 is co-located with each of the fluid flow segments. Specifically, there is a liquid detection sensor rope 23 co-located with each principal fluid flow segment 32 and with each bypass fluid flow segment 42. The liquid detection sensor ropes 23 may be wrapped around the tubing of each fluid flow segment 32, 42 or otherwise positioned where it is most likely to be in contact with liquid leaking from the fluid flow segment with which it is co-located. For example, the liquid detection sensor ropes 23 could be positioned under the associated fluid flow segment and/or in a drip tray under a portion of the fluid flow segment (see also FIG. 6).

While not shown in FIG. 4A, a baseboard management controller 50 (see FIG. 1) is connected to each of the liquid detection sensor ropes 23 and each of the electrically controllable valves 30. Furthermore, connections are formed so that the baseboard management controller 50 is able associate the output signal received from a particular liquid detection sensor rope 23 with the electrically controllable upstream and downstream valves 30 in the same fluid flow segment. As a result of this association, the baseboard management controller 50 is able to receive a positive liquid detection signal from a liquid detection sensor rope 23 and send a control signal to the electrically controllable upstream and downstream valves 30 in the same fluid flow segment as the liquid detection sensor rope 23 that sent the signal. In other words, a leak detection signal originating from a liquid detection sensor rope in one of the fluid flow segments causes the closing of the appropriate valves in that same fluid flow segment so that the liquid coolant is no longer able to flow into the leaking fluid flow segment.

FIG. 4B is a diagram of the liquid-cooling flow loop 20A of FIG. 4A in which the liquid sensor strings or ropes 23 (See FIG. 4A) have been replaced with discrete liquid sensor elements 12 (eighteen shown) according to some embodiments. There is no limit to the number of sensor elements 12 that may be used, but there is preferably at least one sensor element 12 co-located with each fluid flow segment 32, 42 (see FIG. 4A). However, the baseboard management controller 50 will associate all of the sensor elements 12 that are co-located with a given fluid flow segment 32, 42 with the valves in that same given fluid flow segment. Other than the type and number of liquid detection sensors shown in FIG. 4B, the flow loop 20A in FIG. 4B may be operated in the same manner as in FIG. 4A.

FIG. 5A is a diagram of the liquid-cooling flow loop 20A of FIG. 4A identifying a manner in which the electrically controllable valves 30 may be operated to maintain the flow of liquid coolant to the cold plates 22 in thermal communication with heat generating components 24, 26 when none of the liquid detection sensor ropes 23 are detecting liquid according to some embodiments. Liquid coolant flows under a pressure differential between the coolant source 31 and the coolant return 33 through the flow loop 20A. The baseboard management controller 50 (now shown; see FIG. 1) is connected for electronic communication with the liquid detection sensor ropes 23, but none of the liquid detection sensor ropes 23 are sending a positive liquid according detection signal. Accordingly, the baseboard management controller 50 will operate the flow loop 20A in a normal, leak-free manner. One or more electrically controllable valves 30 in each of the bypass fluid flow segments 42 (see FIG. 4A) are closed (illustrated by the bold “X” over the valve) to prevent liquid coolant flow through the bypass fluid flow segments and direct all of the liquid coolant flow through the cold plates 22. This embodiment has a pair of parallel, principal fluid flow segments 32 (see FIG. 4A) that are capable of delivering liquid coolant to and from each of the cold plates 22. For maximum cooling, both of the principal fluid flow segments may deliver liquid coolant to and from the cold plates 22 (illustrated by the bold arrows over the principal fluid flow segment) by opening the electrically controllable upstream and downstream valves 30 in both of the principal fluid flow segments.

Note that the liquid coolant flowing out of the pair of principal fluid flow segments of one cold plate 22, such as the cold plate 22 cooling the DIMM 26 on the left-hand side, may flow through the manifold 46 (illustrated by the bold arrows over the manifold) to the pair of principal fluid flow segments of another cold plate 22, such as the cold plate 22 cooling the CPU 24 on the left-hand side). Note that the manifold 46 will be full of liquid coolant that may flow from any one or more inlets 47 to any one or more of the outlets 48. However, since the pair of principal fluid flow segments delivering liquid coolant to cool the DIMM 26 are open and the pair of principal fluid flow segments delivering liquid coolant to cool the CPU 24 are open, the net flow through the manifold 46 has been illustrated as passing straight through the manifold. While the upper manifold 46 may have a different configuration, there is still liquid coolant flowing from a first pair of principal fluid flow segments to a second, downstream pair of principal fluid flow segment.

FIG. 5B is a diagram of the liquid-cooling flow loop 20A of FIG. 5A identifying a manner in which the electrically controllable valves 30 may be operated to maintain the flow of the liquid coolant to the cold plates 22 while shutting off the flow of liquid coolant to leaking segments of the flow loop when the liquid detection sensor ropes 23 have detected liquid (leaks) in four specific fluid flow segments of the flow loop according to some embodiments. Note that this example includes four leaks for the purpose of describing how the baseboard management controller 50 may respond to the leaks and to illustrate the resilient flow pathways that enable continued operation of the flow loop 20A, albeit at a potentially reduced capacity for heat removal from one or more of the components 24, 26.

The condition and operation of the flow loop 20A may be described in reference to a series of four regions, including a first region 150, a second region 152, a third region 154, and a fourth region 156, which are connected one to the next by one of the manifolds 46.

In the first region 150, the liquid detection sensor rope 23 co-located with the left-hand principal fluid flow segment has detected liquid coolant and is generating a positive liquid detection signal (illustrated by the bold rope and the “(+)” symbol). The baseboard management controller 50 (not shown; see FIG. 1) receives the positive liquid detection signal from the liquid detection sensor rope 23, executes its valve control logic 57 and sends a control signal to the valves 30 in the same principal fluid flow segment causing the valves 30 to close (illustrated by the bold “X” over the valves). However, the valves 30 in the parallel principal fluid flow segment are kept open so that liquid coolant flows therethrough (illustrated by the bold arrow over the principal fluid flow segment). In this illustration of the first region 150, the baseboard management controller 50 keeps the bypass fluid flow segment closed, such that all of the liquid coolant flow passes through the single, principal fluid flow segment with open valves 30.

In the second region 152, the liquid detection sensor rope 23 co-located with the right-hand principal fluid flow segment has detected liquid coolant and is generating a positive liquid detection signal (illustrated by the bold rope and the “(+)” symbol). The baseboard management controller 50 (not shown; see FIG. 1) receives the positive liquid detection signal from the liquid detection sensor rope 23, executes its valve control logic 57 and sends a control signal to the valves 30 in the same principal fluid flow segment causing the valves 30 to close (illustrated by the bold “X” over the valves). However, the valves 30 in the parallel principal fluid flow segment are kept open so that liquid coolant flows therethrough (illustrated by the bold arrow over the principal fluid flow segment). In this illustration of the second region 152, the baseboard management controller 50 keeps the bypass fluid flow segment closed, such that all of the liquid coolant flow passes through the single, principal fluid flow segment with open valves 30. However, notice that, as a result of the valve operations in the first and second regions 150, 152, the flow of liquid coolant through the manifold 46 between the first and second regions 150, 152 enters in the middle inlet 47 and exits from the left-most outlet 48.

In the third region 154, the liquid detection sensor ropes 23 co-located with both principal fluid flow segments have detected liquid coolant and are generating a positive liquid detection signal (illustrated by the bold ropes and the “(+)” symbols). The baseboard management controller 50 (not shown; see FIG. 1) receives the positive liquid detection signals from both liquid detection sensor ropes 23, executes its valve control logic 57, sends control signals to the valves 30 in the principal fluid flow segments causing these four valves 30 to close (illustrated by the bold “X” over the valves) and sends a control signal to the valves 30 in the bypass fluid flow segment causing those valves 30 to open so that the liquid coolant flows through the bypass (illustrated by the bold arrow over the principal fluid flow segment). In this illustration of the third region 154, the baseboard management controller 50 has cut off all of the liquid coolant flow to the cold plate 22 that was cooling the CPU 24, so the baseboard management controller 50 will preferably also shut down the CPU 24. While the shutdown of the CPU will have a negative effect on performance of the server, it is a technical benefit of the flow loop 20A that the other CPU 24 and the two DIMMs 26 are still being cooled and may continue to operate. Accordingly, the apparatus enables the server to be more productive and enables maintenance of the leaking fluid flow segments to be delayed until the next scheduled maintenance for the server while also quickly shutting down the flow of liquid coolant to fluid flow segments that are leaking. It is instructive to notice how the liquid coolant flows through the upper manifold 46 from the left-hand principal fluid flow segment in the second region 152 to the bypass fluid flow segment in the third region 154.

In the fourth region 156, neither of the liquid detection sensor ropes 23 detect the presence of the liquid coolant. Accordingly, the four valves 30 of the two parallel principal fluid flow segments remain open to enable the flow of liquid coolant through the cold plate 22 (illustrated by the bold arrows over the principal fluid flow segments) and the valves 30 in the bypass fluid flow segment remain closed (illustrated by the bold “X” over the valves).

FIG. 6 is a side view of a principal fluid flow segment 32 of the liquid-cooling flow loop including a cold plate 22 and upstream and downstream flow control valves 30. Note that a second, similar principal fluid flow segment may also be incorporated with the same cold plate 22. The cold plate 22 is positioned in thermal communication with the top surface of the CPU 24 that is supported on a system board 160. For each principal fluid flow segment 32 that delivers liquid coolant to this cold plate 22, the cold plate 22 will include an inlet 35, an outlet 36, and a set of internal channels 162 (illustrated in dashed lines) through the body of the cold plate 22 from the inlet 35 to the outlet 36. Accordingly, heat generated by the CPU 24 is conducted into the body of the cold plate 22 and carried away in the liquid coolant that flows through the channels 162. With the two electrically controllable valves 30 in an open condition, liquid coolant flows from an outlet 48 of one manifold through the upstream valve 30, a first piece of tubing 34, the cold plate inlet 35, the internal channels 162 in the cold plate 22, the cold plate outlet 36, the second piece of tubing 37, the downstream valve 30, and the inlet 47 to another manifold.

The liquid detection sensor rope 23 is wrapped around the pieces of tubing 34, 37, passes near the upstream and downstream valves 30 and the cold plate inlet 35 and the cold plate outlet 36, and may also be positioned under the any or all of the fluid flow segment 32. On the left-hand side of the cold plate 22, the liquid detection sensor rope 23 is illustrated passing through a drip tray 164 to detect any liquid coolant accumulating in the drip tray. On the right-hand side of the cold plate 22, the liquid detection sensor rope 23 is illustrated passing across the system board 160 where there may be liquid coolant if the fluid flow segment 32 should leak.

If the baseboard management controller receives a positive liquid detection signal from the liquid detection sensor rope 23, then the baseboard management controller may take steps to remediate the liquid coolant that has leaked out of the fluid flow segment. Specifically, the baseboard management controller may turn on a fan 166 or increase the speed of the fan 166 to cause sufficient air flow through the area of the fluid flow segment 32 to evaporate the leaked liquid coolant in an accelerated manner. Evaporating the liquid coolant quickly may prevent damage to components on the system board 160 or prevent additional damage as a result of the liquid coolant spreading into other areas of the system board or beyond. As an alternative to the use of the fan 166 or in addition to the use of the fan 166, the baseboard management controller may activate one or more thin film heaters 168 in the drip tray 164 and/or on the system board 160 to evaporate the leaked liquid coolant in an accelerated manner.

As will be appreciated by one skilled in the art, embodiments may take the form of a system, method or computer program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a computer program product embodied in one or more computer readable medium(s) having computer readable program code embodied thereon.

Any combination of one or more computer readable storage medium(s) may be utilized. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device. Furthermore, any program instruction or code that is embodied on such computer readable storage media (including forms referred to as volatile memory) that is not a transitory signal are, for the avoidance of doubt, considered “non-transitory”.

Program code embodied on a computer readable storage medium may be transmitted using any appropriate medium, including but not limited to wireless, wireline, optical fiber cable, RF, etc., or any suitable combination of the foregoing. Computer program code for carrying out various operations may be written in any combination of one or more programming languages, including an object-oriented programming language such as Java, Smalltalk, C++ or the like and conventional procedural programming languages, such as the "C" programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Embodiments may be described with reference to flowchart illustrations and/or block diagrams of methods, apparatus (systems) and computer program products. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, and/or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored on computer readable storage media is not a transitory signal, such that the program instructions can direct a computer, other programmable data processing apparatus, or other devices to function in a particular manner, and such that the program instructions stored in the computer readable storage medium produce an article of manufacture.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods and computer program products. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to limit the scope of the claims. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the embodiment.

The corresponding structures, materials, acts, and equivalents of all means or steps plus function elements in the claims below are intended to include any structure, material, or act for performing the function in combination with other claimed elements as specifically claimed. Embodiments have been presented for purposes of illustration and description, but it is not intended to be exhaustive or limited to the embodiments in the form disclosed. Many modifications and variations will be apparent to those of ordinary skill in the art after reading this disclosure. The disclosed embodiments were chosen and described as non-limiting examples to enable others of ordinary skill in the art to understand these embodiments and other embodiments involving modifications suited to a particular implementation.

What is claimed is:

1. An apparatus, comprising:
a server including a plurality of heat generating components;
a flow loop for providing a liquid coolant to a plurality of cold plates, wherein each cold plate is positioned in thermal communication with one of the heat generating components, and wherein the flow loop includes, for each cold plate, one or more fluid flow segments for delivering the liquid coolant to and from the cold plate, wherein each of the one or more fluid flow segments includes an electrically controllable upstream valve at an upstream end of the fluid flow segment and an electrically controllable downstream valve at a downstream end of the fluid flow segment;
a plurality of liquid detection sensors, wherein each liquid detection sensor is co-located with a respective one of the fluid flow segments; and
a controller included in the server and connected to each of the liquid detection sensors, each of the electrically controllable upstream valves and each of the electrically controllable downstream valves, wherein the controller includes a processor configured to process program instructions, wherein the program instructions are configured to, when processed by the processor, cause the processor to perform operations comprising:
receiving, from one or more of the liquid detection sensors, a positive liquid detection signal indicating that the liquid coolant has contacted the liquid detection sensor; and
sending, for each positive liquid detection signal received, a valve control signal to close the electrically controllable upstream valve and the electrically controllable downstream valve of the fluid flow segment that includes the liquid detection sensor that generated the positive liquid detection signal.

2. The apparatus of claim 1, wherein the plurality of heat-generating components include one or more central processing units, one or more graphics processing units, one or more memory modules, one or more hard drives and/or one or more expansion cards.

3. The apparatus of claim 1, wherein the flow loop includes, for each cold plate, first and second fluid flow segments for delivering liquid to and from the cold plate, wherein the first fluid flow segment has a flow path that is independent from the flow path of the second fluid flow segment.

4. The apparatus of claim 1, wherein the flow loop further includes, for a first cold plate of the plurality of cold plates, a liquid bypass fluid flow segment that directs at least some of the liquid coolant to a path isolated from the first cold plate, wherein the liquid bypass fluid flow segment includes one or more electrically controllable valves.

5. The apparatus of claim 4, wherein the liquid bypass fluid flow segment includes first and second electrically controllable valves, the apparatus further comprising:
a liquid detection sensor co-located with the liquid bypass fluid flow segment, wherein the controller is connected to the liquid detection sensor that is co-located with the liquid bypass fluid flow segment, the first electrically controllable valve and the second electrically controllable valve.

6. The apparatus of claim 5, wherein the flow loop includes, for each cold plate, first and second fluid flow segments for delivering liquid to and from the cold plate, wherein the first fluid flow segment has a flow path that is independent from the flow path of the second fluid flow segment.

7. The apparatus of claim 6, wherein the operations further comprise:
monitoring, for each fluid flow segment that delivers the liquid coolant to and from one of the cold plates, output from the liquid detection sensor that is co-located with the fluid flow segment; and
causing, for each fluid flow segment that delivers the liquid coolant to and from one of the cold plates, the electrically controllable upstream valve and the electrically controllable downstream valve at the ends of the fluid flow segment to be open so that liquid flows to and from the cold plate through the fluid flow segment in response to the output from the liquid detection sensor that is co-located with the fluid flow segment indicating that the liquid detection sensor is not in contact with the liquid.

8. The apparatus of claim 7, wherein the operations further comprise:
causing, in response to receiving a positive liquid detection signal from the liquid detection sensor in one of the first and second fluid flow segments that deliver the liquid coolant to and from one of the cold plates, the one or more electrically controllable valves in the liquid bypass fluid flow segment to open.

9. The apparatus of claim 8, wherein the operations further comprise:
causing, in response to receiving a positive liquid detection signal from the liquid detection sensor in both of the first and second fluid flow segments that deliver the liquid coolant to and from one of the cold plates, the one or more electrically controllable valves in the liquid bypass fluid flow segment to open and the heat generating component that is in thermal communication with the cold plate to be taken offline.

10. The apparatus of claim 1, wherein the operations further comprise:
causing, in response to receiving a positive liquid detection signal from the liquid detection sensor in each of the one or more fluid flow segments that deliver the liquid coolant to and from one of the cold plates, the heat generating component that is in thermal communication with the cold plate to be taken offline and the one or more electrically controllable valves in the liquid bypass fluid flow segment to open.

11. The apparatus of claim 10, wherein the operations further comprise:
allowing the server to continue in operation after the heat generating component has been taken offline.

12. The apparatus of claim 1, wherein, for each of the electrically controllable upstream valves and for each of the electrically controllable downstream valves, the valve includes a closure element that is coupled to an electronic actuator, and wherein the electronic actuator is adapted to move the closure element to open or close the valve responsive to the valve control signal received by the valve.

13. The apparatus of claim 12, wherein the electrically controllable upstream and downstream valves are electric solenoid valves and the liquid detection sensors are liquid sensor strings or ropes.

14. The apparatus of claim 1, wherein the flow loop includes at least one fluid flow segment that delivers the liquid coolant to and from two or more cold plates in series.

15. The apparatus of claim 1, wherein the flow loop includes a plurality of manifolds, wherein each manifold is connected to a plurality of electrically controllable downstream valves at the downstream end of the fluid flow segments delivering the liquid coolant to a first one of the cold plates and/or a plurality of electrically controllable upstream valves at the upstream end of the fluid flow segments delivering the liquid coolant to a second one of the cold plates.

16. The apparatus of claim 15, wherein the flow loop further includes, for a first cold plate of the plurality of cold plates, a liquid bypass fluid flow segment that directs at least some of the liquid coolant to a path isolated from the first cold plate, wherein the liquid bypass fluid flow segment includes one or more electrically controllable valves, and wherein, for two or more of the manifolds, the manifolds are further connected to the liquid bypass fluid flow segment that directs at least some of the liquid coolant to the path isolated from the first cold plate.

17. The apparatus of claim 1, further comprising:
a coolant distribution unit in fluid communication with the flow loop, wherein the coolant distribution unit supplies the liquid coolant to an upstream end of the flow loop and receives the liquid coolant from a downstream end of the flow loop.

18. The apparatus of claim 1, further comprising:
a thin film heater positioned under the fluid flow segment, wherein the operations further comprise:
controlling the thin film heater to increase evaporation of liquid present under the fluid flow segment in response to receiving the positive liquid detection signal from one or more of the liquid detection sensors within that particular fluid flow segment.

19. The apparatus of claim 1, further comprising:
one or more fans directed to cause air flow across the fluid flow segment, wherein the operations further comprise:
increasing the speed of the one or more fans to increase evaporation of liquid present under the fluid flow segment in response to receiving the positive liquid detection signal from one or more of the liquid detection sensors within that particular fluid flow segment.

20. An apparatus, comprising:
a server including a first plurality of heat generating components and a second plurality of heat generating components;
a first flow loop for providing a liquid coolant to a first plurality of cold plates that are each positioned in thermal communication with one of the heat generating components in the first plurality of heat generating components and a second flow loop for providing the liquid coolant to a second plurality of cold plates that are each positioned in thermal communication with one of the heat generating components in the second plurality of heat generating components, wherein each of the first and second flow loops include, for each cold plate, one or more fluid flow segments for delivering the liquid coolant to and from the cold plate, wherein each of the one or more fluid flow segments includes an electrically controllable upstream valve at an upstream end of the fluid flow segment and an electrically controllable downstream valve at a downstream end of the fluid flow segment;
a plurality of liquid detection sensors, wherein each liquid detection sensor is co-located with a respective one of the fluid flow segments; and
a controller included in the server and connected to each of the liquid detection sensors, each of the electrically controllable upstream valves and each of the electrically controllable downstream valves, wherein the controller includes a processor configured to process program instructions, wherein the program instructions are configured to, when processed by the processor, cause the processor to perform operations comprising:
receiving, from one or more of the liquid detection sensors, a positive liquid detection signal indicating that the liquid coolant has contacted the liquid detection sensor; and
sending, for each positive liquid detection signal received, a valve control signal to close the electrically controllable upstream valve and the electrically controllable downstream valve of the fluid flow segment that includes the liquid detection sensor that generated the positive liquid detection signal.
